(19) United States
(12) Patent Application Publication
(10) Pub. No.: US 2026/0052995 A1
(43) Pub. Date: Feb. 19, 2026

(54) WAFER-TO-WAFER BONDING STRUCTURE AND FABRICATION METHOD THEREOF

(71) Applicant: UNITED MICROELECTRONICS CORP., Hsin-Chu City (TW)

(72) Inventors: Yao-Hsien Chung, Tainan City (TW); Fu-Yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/893,991

(22) Filed: Sep. 24, 2024

(30) Foreign Application Priority Data
Aug. 16, 2024 (TW) 113130816

(51) Int. Cl. H01L 23/00; H01L 23/544; H01L 25/065

(52) U.S. Cl. CPC H01L 24/29; H01L 23/544; H01L 23/562; H01L 24/27; H01L 24/32; H01L 24/83; H01L 25/0657; H01L 2224/27614; H01L 2224/2762; H01L 2224/29011; H01L 2224/29082; H01L 2224/29187; H01L 2224/32145; H01L 2224/83141; H01L 2224/83193; H01L 2224/83896; H01L 2225/06565

(57) ABSTRACT

A wafer-to-wafer bonding structure includes a first wafer having a first bonding layer thereon, a first main pattern region, a first scribe lane surrounding the first main pattern region, and a first alignment cavity disposed in the first bonding layer within the first main pattern region; and a second wafer having a second bonding layer bonded to the first bonding layer, a second main pattern region, a second scribe lane surrounding the second main pattern region, and a second alignment cavity disposed in the second bonding layer within the second main pattern region.

### BACKGROUND OF THE INVENTION

### 1. Field of the Invention

The present invention relates to the field of semiconductor technology, and in particular to an improved wafer-to-wafer bonding structure and a manufacturing method thereof.

### 2. Description of the Prior Art

Vertical stacking of semiconductor devices has become an increasingly viable approach to enabling continuous improvements in device density and performance. Wafer-to-wafer bonding is an essential process step to enable 3D stacked devices.

Current wafer-to-wafer oxide bonding faces the dilemma of insufficient alignment accuracy. This is due to the lack of suitable alignment marks (no metal patterns are formed in the bonding oxide layer), so mechanical alignment is usually the only option. The notch of the wafer is used as the reference for alignment, and then fine-tuned through the machine. However, the error may reach 100-200 micrometers.

### SUMMARY OF THE INVENTION

It is one object of the present invention to provide an improved wafer-to-wafer bonding structure and its manufacturing method to solve the shortcomings or deficiencies of the existing technology.

One aspect of the invention provides a wafer-to-wafer bonding structure including a first wafer having a first bonding layer thereon, a first main pattern region, a first scribe lane surrounding the first main pattern region, and a first alignment cavity disposed in the first bonding layer within the first main pattern region; and a second wafer having a second bonding layer bonded to the first bonding layer, a second main pattern region, a second scribe lane surrounding the second main pattern region, and a second alignment cavity disposed in the second bonding layer within the second main pattern region.

According to some embodiments, the first bonding layer and the second bonding layer are dielectric layers.

According to some embodiments, the first bonding layer and the second bonding layer comprise a silicon oxide layer, a nitrogen-doped silicon carbide layer, or a combination thereof.

According to some embodiments, no metal structure is formed in the first bonding layer or the second bonding layer.

According to some embodiments, the first alignment cavity is offset from the second alignment cavity.

According to some embodiments, the first alignment cavity is composed of four outer cavity patterns, wherein each of the four outer cavity patterns comprises a first cavity having a first length and a second cavity having a second length that is different from the first length.

According to some embodiments, the second alignment cavity is composed of four inner cavity patterns, wherein each of the four inner cavity patterns comprises a third cavity having a third length and a fourth cavity having a fourth length that is different from the third length.

According to some embodiments, the first length is equal to the third length, and wherein the second length is equal to the fourth length.

According to some embodiments, the first length and the third length are between 10-15 micrometers.

According to some embodiments, the second length and the fourth length are between 3-5 micrometers.

Another aspect of the invention provides a method for forming a wafer-to-wafer bonding structure. A first wafer and a second wafer are provided. The first wafer includes a first bonding layer thereon, a first main pattern region, a first scribe lane surrounding the first main pattern region, and a first alignment cavity disposed in the first bonding layer within the first main pattern region. The second wafer includes a second bonding layer, a second main pattern region, a second scribe lane surrounding the second main pattern region, and a second alignment cavity disposed in the second bonding layer within the second main pattern region. The first wafer is aligned with the second wafer by scanning the first alignment cavity and the second alignment cavity, respectively. The first bonding layer of the first wafer is bonded to the second bonding layer of the second wafer, thereby forming the wafer-to-wafer bonding structure.

According to some embodiments, the first bonding layer and the second bonding layer are dielectric layers.

According to some embodiments, the first bonding layer and the second bonding layer comprise a silicon oxide layer, a nitrogen-doped silicon carbide layer, or a combination thereof.

According to some embodiments, no metal structure is formed in the first bonding layer or the second bonding layer.

According to some embodiments, the first alignment cavity is offset from the second alignment cavity.

According to some embodiments, the first alignment cavity is composed of four outer cavity patterns, wherein each of the four outer cavity patterns comprises a first cavity having a first length and a second cavity having a second length that is different from the first length.

According to some embodiments, the second alignment cavity is composed of four inner cavity patterns, wherein each of the four inner cavity patterns comprises a third cavity having a third length and a fourth cavity having a fourth length that is different from the third length.

According to some embodiments, the first length is equal to the third length, and wherein the second length is equal to the fourth length.

According to some embodiments, the first length and the third length are between 10-15 micrometers.

According to some embodiments, the second length and the fourth length are between 3-5 micrometers.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 are schematic diagrams showing a method for forming a wafer-to-wafer bonding structure according to an embodiment of the present invention, wherein:

FIG. 1 and FIG. 2 illustrate a method of manufacturing the first wafer;

FIG. 3 and FIG. 4 illustrate a method of manufacturing the second wafer;

FIG. 5 illustrates a top view of the first alignment cavity on the first wafer;

FIG. 6 illustrates a top view of the second alignment cavity on the second wafer;

FIG. 7 illustrates a schematic diagram after the first wafer is bonded to the second wafer; and

FIG. 8 illustrates a schematic diagram of the first alignment cavity on the first wafer being aligned with the second alignment cavity on the second wafer.

FIG. 9 is a schematic diagram of a first alignment cavity on a first wafer aligned with a second alignment cavity on a second wafer according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

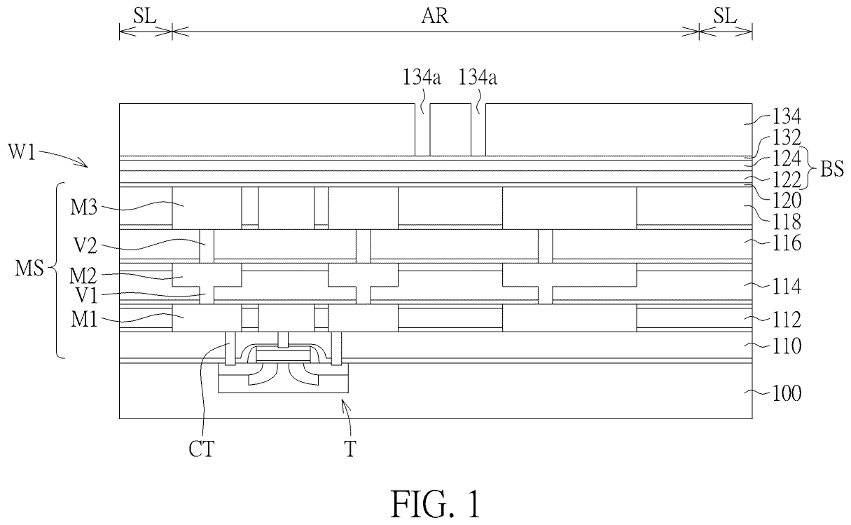

Please refer to FIG. 1 to FIG. 8, which are schematic diagrams showing a method of forming a wafer-to-wafer bonding structure according to an embodiment of the present invention, wherein like layers, regions or components are designated by like numeral numbers or labels. First, as shown in FIG. 1, a first wafer W1 is produced, which includes a substrate 100, for example, a silicon substrate or a silicon-on-insulator (SOI) substrate, but is not limited thereto. According to an embodiment of the present invention, a transistor T, such as an N-type field effect transistor (NFET) or a P-type field effect transistor (PFET), may be formed on the substrate 100. For the sake of simplicity, other structures in the substrate 100, such as insulation structures or ion wells, are not shown.

According to an embodiment of the present invention, a plurality of dielectric layers 110-120 may be formed on the substrate 100. The dielectric layer 110 may include, for example, a silicon oxide layer or a boron-phosphorus silicon glass. The dielectric layers 112, 114, 116, and 118 may, for example, include a low dielectric constant material or an ultra-low dielectric constant material, and the dielectric layer 120 may, for example, include an etching stop layer such as a nitrogen-doped silicon carbide layer, but is not limited thereto.

According to an embodiment of the present invention, a metal interconnect structure MS may be further formed on the substrate 100. For example, the metal interconnect structure MS may include a first metal layer M1, a second metal layer M2 and a third metal layer M3, a contact plug CT electrically connecting the transistor T with the first metal layer M1, a first conductive via V1 electrically connecting the first metal layer M1 with the second metal layer M2, and a second conductive via V2 electrically connecting the second metal layer M2 with the third metal layer M3. According to an embodiment of the present invention, the first metal layer M1, the second metal layer M2, and the third metal layer M3 may be copper metal layers, wherein the third metal layer M3 is, for example, the uppermost copper metal layer.

According to an embodiment of the present invention, a bonding layer BS may be formed on the dielectric layer 120. According to an embodiment of the present invention, the bonding layer BS is a dielectric layer. According to an embodiment of the present invention, the bonding layer BS may include a silicon oxide layer 122 and a nitrogen-doped silicon carbide layer 124, but is not limited thereto. According to an embodiment of the present invention, the bonding layer BS may include a silicon oxide layer, a nitrogen-doped silicon carbide layer, or a combination thereof. According to another embodiment of the present invention, the bonding layer BS may only include the silicon oxide layer 122. According to an embodiment of the present invention, no metal structure is formed in the bonding layer BS. According to an embodiment of the present invention, the first wafer W1 may include a main pattern region AR and a continuous annular scribe lane SL surrounding the main pattern region AR.

Subsequently, a photolithography process is performed to form a bottom anti-reflective layer 132 and a photoresist pattern 134 on the bonding layer BS, wherein an opening 134a is formed in the photoresist pattern 134. According to an embodiment of the present invention, the opening 134a is located in the main pattern region AR. According to an embodiment of the present invention, the opening 134a may not overlap the underlying third metal layer M3, but is not limited thereto.

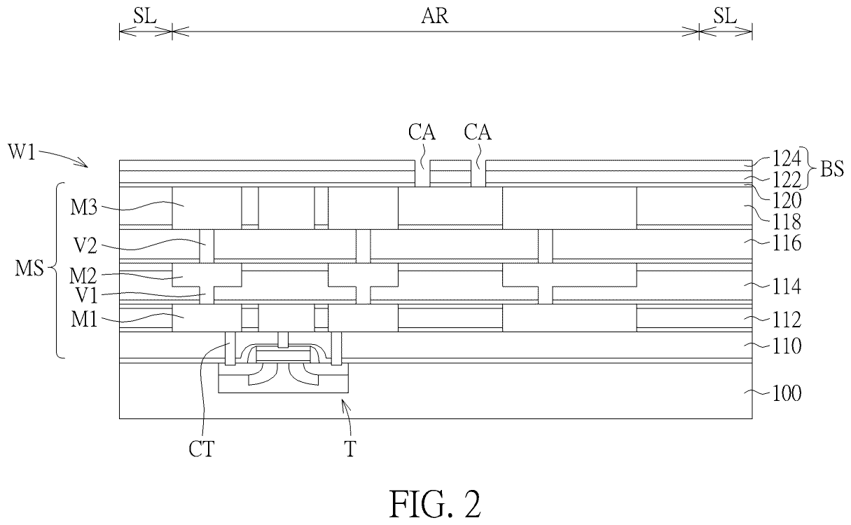

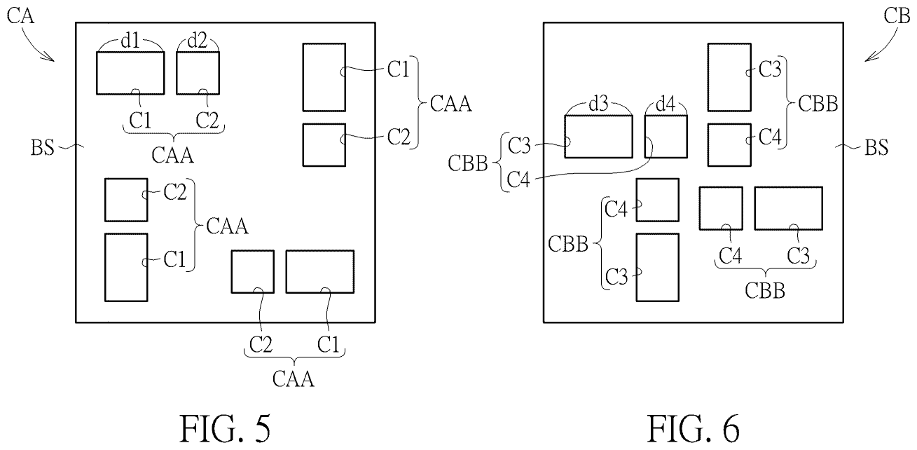

As shown in FIG. 2, an anisotropic dry etching process is performed to etch the bottom anti-reflective layer 132 and the bonding layer BS through the opening 134a in the photoresist pattern 134 thereby forming an alignment cavity CA in the bonding layer BS. As shown in FIG. 5, the alignment cavity CA is composed of four outer cavity patterns CAA, where the four outer cavity patterns CAA may not be connected to each other. According to an embodiment of the present invention, for example, each outer cavity pattern CAA includes a first cavity body C1 with a first length d1 and a second cavity body C2 with a second length d2, where the first length d1 is different from the second length d2. According to an embodiment of the present invention, for example, the first length d1 is greater than the second length d2. According to an embodiment of the present invention, for example, the first length d1 may be between 10-15 micrometers. According to an embodiment of the present invention, for example, the second length d2 may be between 3-5 micrometers.

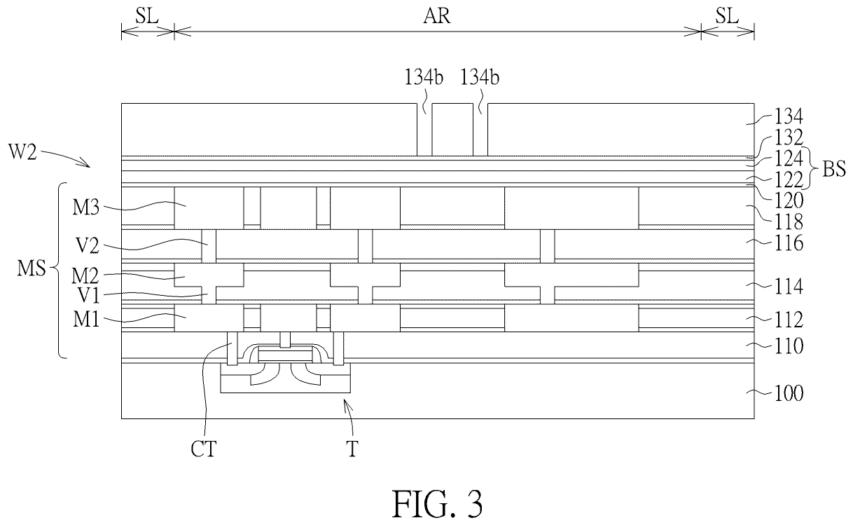

As shown in FIG. 3, a second wafer W2 is produced, which also includes a substrate 100, such as a silicon substrate or a silicon-on-insulator substrate, but is not limited thereto. According to an embodiment of the present invention, a transistor T, such as an N-type field effect transistor or a P-type field effect transistor, may be formed on the substrate 100. For the sake of simplicity, other structures in the substrate 100, such as insulation structures or ion wells, are not shown.

According to an embodiment of the present invention, a plurality of dielectric layers 110-120 may also be formed on the substrate 100, where the dielectric layer 110 may include, for example, a silicon oxide layer or a boron phosphorus silicon glass, etc., and the dielectric layers 112, 114, 116, and 118 may, for example, include a low dielectric constant material or an ultra-low dielectric constant material, etc., and the dielectric layer 120 may, for example, include an etching stop layer such as a nitrogen-doped silicon carbide layer, but is not limited thereto.

According to an embodiment of the present invention, a metal interconnect structure MS may be further formed on the substrate 100. For example, the metal interconnect structure MS may include a first metal layer M1, a second metal layer M2 and a third metal layer M3, a contact plug CT electrically connecting the transistor T with the first metal layer M1, a conductive via V1 electrically connecting the first metal layer M1 with the second metal layer M2, and a conductive via V2 electrically connecting the second metal layer M2 with the third metal layer M3. According to an embodiment of the present invention, the first metal layer M1, the second metal layer M2, and the third metal layer M3 may be copper metal layers, wherein the third metal layer M3 is, for example, the uppermost copper metal layer.

According to an embodiment of the present invention, a bonding layer BS may be formed on the dielectric layer 120. According to an embodiment of the present invention, the bonding layer BS is a dielectric layer. According to an embodiment of the present invention, the bonding layer BS may include a silicon oxide layer 122 and a nitrogen-doped silicon carbide layer 124, but is not limited thereto. According to an embodiment of the present invention, the bonding layer BS may include a silicon oxide layer, a nitrogen-doped silicon carbide layer, or a combination thereof. According to another embodiment of the present invention, the bonding layer BS may only include the silicon oxide layer 122. According to an embodiment of the present invention, no metal structure is formed in the bonding layer BS. According to an embodiment of the present invention, the second wafer W2 may include a main pattern region AR and a continuous annular scribe lane SL surrounding the main pattern region AR.

Next, a photolithography process is performed to form a bottom anti-reflective layer 132 and a photoresist pattern 134 on the bonding layer BS, where an opening 134b is formed in the photoresist pattern 134. According to an embodiment of the present invention, the opening 134b is also located in the main pattern region AR. According to an embodiment of the present invention, the opening 134b may not overlap the lower third metal layer M3, but is not limited thereto.

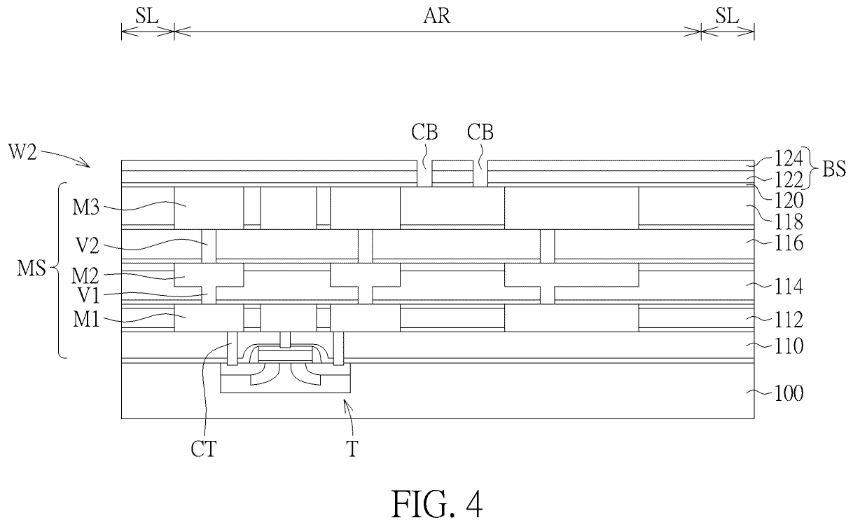

As shown in FIG. 4, an anisotropic dry etching process is performed, and the bottom anti-reflective layer 132 and the bonding layer BS are etched through the opening 134b in the photoresist pattern 134 thereby forming an alignment cavity CB in the bonding layer BS. As shown in FIG. 6, the alignment cavity CB is composed of four inner cavity patterns CBB, where the four inner cavity patterns CBB may not be connected to each other. According to an embodiment of the present invention, for example, each inner cavity pattern CBB includes a third cavity body C3 with a third length d3 and a fourth cavity body C4 with a fourth length d4, where the third length d3 is different from the fourth length d4. According to an embodiment of the present invention, for example, the third length d3 is greater than the fourth length d4. According to an embodiment of the present invention, for example, the third length d3 may be between 10-15 micrometers.

According to an embodiment of the present invention, for example, the fourth length d4 may be between 3-5 micrometers. According to an embodiment of the present invention, for example, the first length d1 may be equal to the third length d3, and the second length d2 may be equal to the fourth length d4, but is not limited thereto.

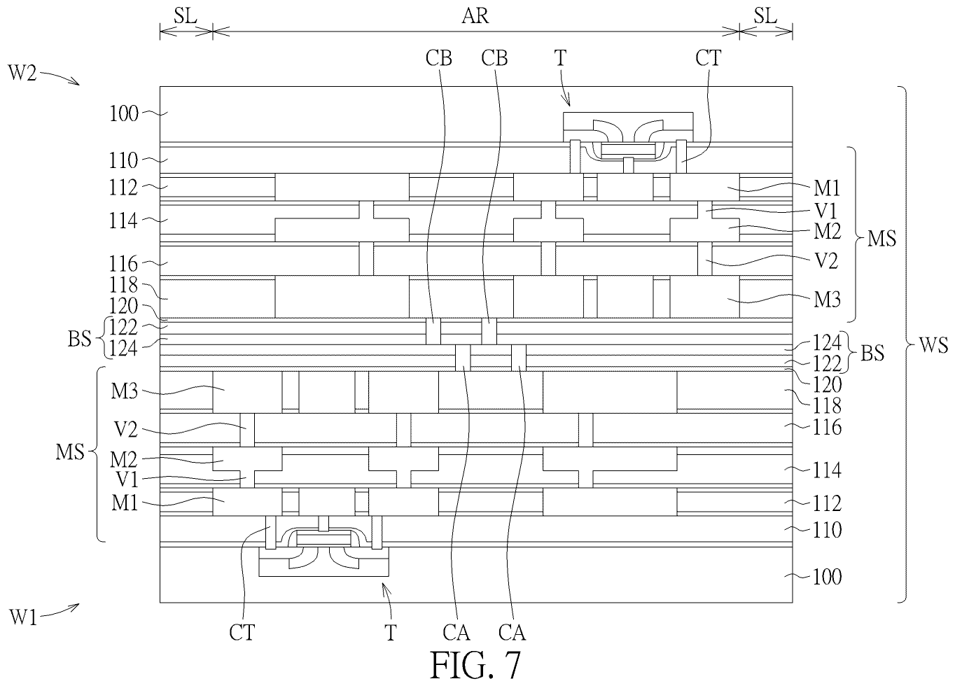

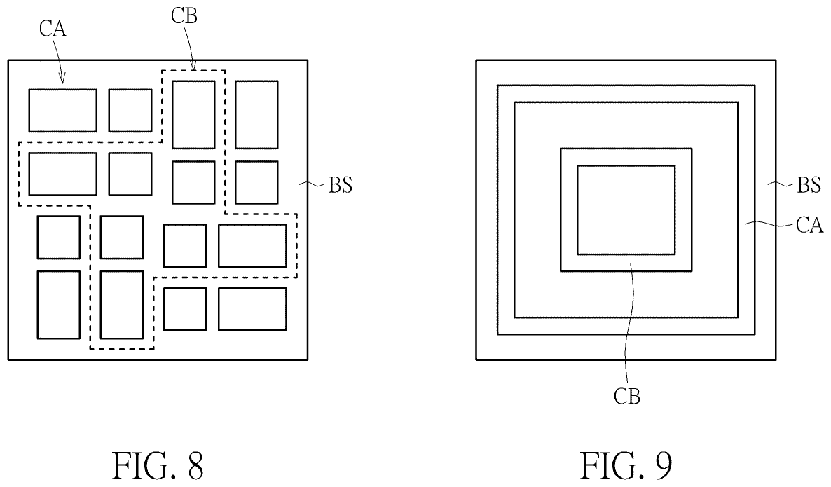

Next, as shown in FIG. 7, wafer-to-wafer bonding is performed in the wafer bonding tool. The wafers are aligned face-to-face through cameras or optical components on wafer bonding tool. As shown in FIG. 8, the alignment cavity CA of the first wafer W1 is offset from the alignment cavity CB of the second wafer W2 (within the dotted line area), so that the first wafer W1 can be aligned with high accuracy (error less than 60 nm) and align the second wafer W2. After alignment, bonding is performed so that the bonding layer BS of the first wafer W1 is directly bonded to the bonding layer BS of the second wafer W2 to form a wafer bonding structure WS.

FIG. 9 is a schematic diagram of an alignment cavity on a first wafer aligned with an alignment cavity on a second wafer according to another embodiment of the present invention. As shown in FIG. 9, the alignment cavity CA of the first wafer W1 and the alignment cavity CB of the second wafer W2 may be a continuous ring pattern. When the wafers are aligned face-to-face through the camera or optical components on the wafer bonding tool, the alignment cavity CA of the first wafer W1 is also offset from the alignment cavity CB of the second wafer W2, achieving high accuracy (error less than 60 nm) alignment.

Another advantage of the present invention is that the alignment cavity CA is arranged in the main pattern region AR rather than in the scribe lane SL, which can avoid the cracks caused by stress, which affects the reliability of the chip, from spreading to the main pattern region AR through the alignment cavity CA during wafer dicing.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer-to-wafer bonding structure, comprising:
a first wafer having a first bonding layer thereon, a first main pattern region, a first scribe lane surrounding the first main pattern region, and a first alignment cavity disposed in the first bonding layer within the first main pattern region; and
a second wafer having a second bonding layer bonded to the first bonding layer, a second main pattern region, a second scribe lane surrounding the second main pattern region, and a second alignment cavity disposed in the second bonding layer within the second main pattern region.

2. The wafer-to-wafer bonding structure according to claim 1, wherein the first bonding layer and the second bonding layer are dielectric layers.

3. The wafer-to-wafer bonding structure according to claim 1, wherein the first bonding layer and the second bonding layer comprise a silicon oxide layer, a nitrogen-doped silicon carbide layer, or a combination thereof.

4. The wafer-to-wafer bonding structure according to claim 1, wherein no metal structure is formed in the first bonding layer or the second bonding layer.

5. The wafer-to-wafer bonding structure according to claim 1, wherein the first alignment cavity is offset from the second alignment cavity.

6. The wafer-to-wafer bonding structure according to claim 1, wherein the first alignment cavity is composed of four outer cavity patterns, wherein each of the four outer cavity patterns comprises a first cavity having a first length and a second cavity having a second length that is different from the first length.

7. The wafer-to-wafer bonding structure according to claim 6, wherein the second alignment cavity is composed of four inner cavity patterns, wherein each of the four inner cavity patterns comprises a third cavity having a third length and a fourth cavity having a fourth length that is different from the third length.

8. The wafer-to-wafer bonding structure according to claim 7, wherein the first length is equal to the third length, and wherein the second length is equal to the fourth length.

9. The wafer-to-wafer bonding structure according to claim 8, wherein the first length and the third length are between 10-15 micrometers.

10. The wafer-to-wafer bonding structure according to claim 8, wherein the second length and the fourth length are between 3-5 micrometers.

11. A method for forming a wafer-to-wafer bonding structure, comprising:
providing a first wafer having a first bonding layer thereon, a first main pattern region, a first scribe lane surrounding the first main pattern region, and a first alignment cavity disposed in the first bonding layer within the first main pattern region;
providing a second wafer having a second bonding layer, a second main pattern region, a second scribe lane surrounding the second main pattern region, and a second alignment cavity disposed in the second bonding layer within the second main pattern region;
aligning the first wafer with the second wafer by scanning the first alignment cavity and the second alignment cavity, respectively; and
bonding the first bonding layer of the first wafer to the second bonding layer of the second wafer, thereby forming the wafer-to-wafer bonding structure.

12. The method according to claim 11, wherein the first bonding layer and the second bonding layer are dielectric layers.

13. The method according to claim 11, wherein the first bonding layer and the second bonding layer comprise a silicon oxide layer, a nitrogen-doped silicon carbide layer, or a combination thereof.

14. The method according to claim 11, wherein no metal structure is formed in the first bonding layer or the second bonding layer.

15. The method according to claim 11, wherein the first alignment cavity is offset from the second alignment cavity.

16. The method according to claim 11, wherein the first alignment cavity is composed of four outer cavity patterns, wherein each of the four outer cavity patterns comprises a first cavity having a first length and a second cavity having a second length that is different from the first length.

17. The method according to claim 16, wherein the second alignment cavity is composed of four inner cavity patterns, wherein each of the four inner cavity patterns comprises a third cavity having a third length and a fourth cavity having a fourth length that is different from the third length.

18. The method according to claim 17, wherein the first length is equal to the third length, and wherein the second length is equal to the fourth length.

19. The method according to claim 18, wherein the first length and the third length are between 10-15 micrometers.

20. The method according to claim 18, wherein the second length and the fourth length are between 3-5 micrometers.
